(19) United States
(12) Patent Application Publication
(10) Pub. No.: US 2026/0210870 A1
(43) Pub. Date: Jul. 23, 2026

(54) OPTICAL APPARATUS FOR THREE-DIMENSIONAL NANOSTRUCTURE MEASUREMENT AND INSPECTION, THREE-DIMENSIONAL NANOSTRUCTURE MEASUREMENT AND INSPECTION APPARATUS INCLUDING THE SAME, AND THREE-DIMENSIONAL NANOSTRUCTURE MEASUREMENT AND INSPECTION METHOD

(71) Applicant: SAMSUNG ELECTRONICS CO., LTD., Suwon-si (KR)

(72) Inventors: Seunghoon HAN, Suwon-si (KR); Junghyun PARK, Suwon-si (KR)

(73) Assignee: SAMSUNG ELECTRONICS CO., LTD., Suwon-si (KR)

(21) Appl. No.: 19/365,723

(22) Filed: Oct. 22, 2025

(30) Foreign Application Priority Data
Jan. 21, 2025 (KR) 10-2025-0008533

(51) Int. Cl. G01N 21/88; G01N 21/956; H10P 74/20

(52) U.S. Cl. CPC G01N 21/8806; G01N 21/956; G01N 2021/8829; H10P 74/203

(57) ABSTRACT

An optical apparatus may include an illumination system configured to emit illumination light to a measurement object, a photodetector configured to detect light from the measurement object, and based on the measurement object including a three-dimensional nanostructure and a substrate, and the substrate including a first surface on which the three-dimensional nanostructure is mounted and a second surface that opposes the first surface, a meta deflector configured to be provided on the second surface of the substrate. The illumination system may be configured to emit the illumination light to be obliquely incident on the meta deflector, and the meta deflector may be configured to negatively deflect the illumination light.

### CROSS-REFERENCE TO RELATED APPLICATION

This application is based on and claims priority under 35 U.S.C. § 119 to Korean Patent Application No. 10-2025-0008533, filed on Jan. 21, 2025, in the Korean Intellectual Property Office, the disclosure of which is incorporated by reference herein in its entirety.

### BACKGROUND

### 1. Field

The disclosure relates to an optical apparatus for three-dimensional nanostructure measurement and inspection, a three-dimensional nanostructure measurement and inspection apparatus including the same, and a three-dimensional nanostructure measurement and inspection method.

### 2. Description of the Related Art

A semiconductor device is fabricated by forming a fine nanostructure on a wafer. After the fabrication of the semiconductor device, a measurement and inspection may be performed to verify the nanostructure. In addition to semiconductor devices, various metasurfaces or optical structures used in virtual reality systems or augmented reality systems may have a nanostructure. The measurement and inspection of the nanostructure of semiconductor devices or metasurfaces are mainly performed by irradiating light toward the surface on which the nanostructure is formed and then analyzing the reflected and/or diffracted light. However, according to a front irradiation method, as the total height of a three-dimensional nanostructure increases, it may be difficult to maximally concentrate light on a structural area in which a fine change of the nanostructure occurs.

### SUMMARY

One or more embodiments provide an optical apparatus for three-dimensional nanostructure measurement and inspection, which may improve the measurement accuracy and sensitivity by concentrating light on a structural area in which a fine change of a three-dimensional nanostructure occurs.

One or more embodiments provide a three-dimensional nanostructure measurement and inspection apparatus and a three-dimensional nanostructure measurement and inspection method, with improved measurement accuracy and sensitivity on a three-dimensional nanostructure.

Additional aspects will be set forth in part in the description which follows and, in part, will be apparent from the description, or may be learned by practice of the presented embodiments of the disclosure.

According to an aspect of the disclosure, an optical apparatus may include an illumination system configured to emit illumination light to a measurement object, a photodetector configured to detect light from the measurement object, and based on the measurement object including a three-dimensional nanostructure and a substrate, and the substrate including a first surface on which the three-dimensional nanostructure is mounted and a second surface that opposes the first surface, a meta deflector configured to be provided on the second surface of the substrate. The illumination system may be configured to emit the illumination light to be obliquely incident on the meta deflector, and the meta deflector may be configured to negatively deflect the illumination light.

The meta deflector may include a plurality of meta elements that are periodically provided in two dimensions.

The plurality of meta elements of the meta deflector may include a plurality of first meta elements and a plurality of second meta elements, which are different from each other in terms of at least one of a shape, a size, and a direction, and the plurality of first meta elements and the plurality of second meta elements may be alternately provided in at least one of a first direction or a second direction intersecting the first direction.

An arrangement period of the plurality of meta elements of the meta deflector may be ⅔ or less of a wavelength of the illumination light.

The illumination system may be further configured such that a wavelength, polarization, and an azimuth direction of the illumination light and an incident angle of the illumination light incident on the meta deflector are adjusted.

An incident angle of the illumination light incident on the meta deflector may be set such that the illumination light negatively deflected by the meta deflector is coupled to a leaky guided mode of the three-dimensional nanostructure.

The optical apparatus for three-dimensional nanostructure measurement and inspection may further include a carrier substrate with the meta deflector, wherein the carrier substrate may include a first surface and a second surface opposing each other, the meta deflector may be provided on the first surface of the carrier substrate, and the carrier substrate may be provided such that the first surface of the carrier substrate with the meta deflector faces the second surface of the substrate of the measurement object.

The carrier substrate may be temporarily bonded to the substrate of the measurement object. For example, the carrier substrate may be bonded to the substrate of the measurement object during measurement and inspection, and may be separated from the substrate of the measurement object before and after the measurement and inspection.

The optical apparatus for three-dimensional nanostructure measurement and inspection may further include an additional photodetector configured to investigate a defect of the three-dimensional nanostructure, wherein the additional photodetector may be provided to perpendicularly face a surface of the three-dimensional nanostructure.

The additional photodetector may be provided to face an area in which the illumination light negatively deflected by the meta deflector is incident on the three-dimensional nanostructure.

The illumination system and the photodetector may be configured to scan the three-dimensional nanostructure while moving in at least one of a first direction or a second direction, and the additional photodetector may be configured to move in the first direction and/or the second direction in accordance with a movement of the illumination system.

The photodetector may include a spectroscope or a hyperspectral image sensor and may be configured to detect at least one of a wavelength component, a propagation angle, and a polarization component of incident light.

According to another aspect of the disclosure, a three-dimensional nanostructure measurement and inspection apparatus may include an illumination system configured to emit illumination light to a measurement object; a photodetector configured to detect light from the measurement object; based on the measurement object including a three-dimensional nanostructure and a substrate, and the substrate including a first surface on which the three-dimensional nanostructure is mounted and a second surface that opposes the first surface, a meta deflector is configured to be provided on the second surface of the substrate; and a processor configured to control operations of the illumination system and the photodetector and analyze the three-dimensional nanostructure based on an output of the photodetector, wherein the illumination system is configured to emit the illumination light to be obliquely incident on the meta deflector, and the meta deflector is configured to negatively deflect the illumination light.

The processor may be further configured to calculate an incident angle of the illumination light incident on the meta deflector such that the illumination light negatively deflected by the meta deflector is coupled to a leaky guided mode of the three-dimensional nanostructure.

The meta deflector may include a plurality of meta elements that are periodically provided in two dimensions.

The processor may be further configured to adjust at least one of a wavelength, polarization, and azimuth direction of the illumination light, and the processor may be further configured to calculate the incident angle of the illumination light based on data about an arrangement period of the plurality of meta elements of the meta deflector and data about a waveguide effective index in the leaky guided mode of the three-dimensional nanostructure according to the wavelength, the polarization, the incident angle, and the azimuth direction of the illumination light, and adjust the incident angle of the illumination light based on a result of the calculating.

The measurement object may include a plurality of chips and a test element group (TEG) area provided between two chips among the plurality of chips, and the processor may be further configured to infer data obtained during measurement of the three-dimensional nanostructure, based on a result of measurement performed on the TEG area.

According to another aspect of the disclosure, a method for a measurement object including a substrate, the substrate including a first surface on which a three-dimensional nanostructure is mounted and a second surface opposing the first surface is provided. The method may include arranging a meta deflector on the second surface of the substrate, emitting illumination light to be obliquely incident on the meta deflector, negatively deflecting the illumination light by the meta deflector, coupling the negatively deflected illumination light to a leaky guided mode of the three-dimensional nanostructure, detecting light from the three-dimensional nanostructure by a photodetector, and analyzing the three-dimensional nanostructure based on an output of the photodetector.

The emitting of the illumination light to be obliquely incident on the meta deflector may include calculating an incident angle of the illumination light incident on the meta deflector such that the illumination light negatively deflected by the meta deflector is coupled to the leaky guided mode of the three-dimensional nanostructure, and adjusting the incident angle of the illumination light based on a result of the calculating.

The measurement object may include a plurality of chips and a test element group (TEG) area provided between two chips among the plurality of chips, and the method may further include inferring data obtained during measurement of the three-dimensional nanostructure, based on a result of measurement performed on the TEG area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a schematic configuration of an optical apparatus for three-dimensional nanostructure measurement and inspection and a three-dimensional nanostructure measurement and inspection apparatus according to an embodiment;

FIGS. 2 and 3 illustrate examples of a three-dimensional nanostructure of a measurement object;

FIGS. 4 and 5 illustrate a configuration of a meta deflector according to an embodiment;

FIG. 6 is a graph illustrating relationships between a waveguide effective index in a leaky guided mode of a three-dimensional nanostructure to be measured, an arrangement period of a plurality of meta elements of a meta deflector, and an incident angle of illumination light;

FIG. 7 illustrates a configuration of an illumination system;

FIG. 8 illustrates a schematic configuration of an optical apparatus for three-dimensional nanostructure measurement and inspection and a three-dimensional nanostructure measurement and inspection apparatus according to another embodiment;

FIG. 9 illustrates a schematic configuration of an optical apparatus for three-dimensional nanostructure measurement and inspection and a three-dimensional nanostructure measurement and inspection apparatus according to another embodiment;

FIG. 10 illustrates a schematic configuration of an optical apparatus for three-dimensional nanostructure measurement and inspection and a three-dimensional nanostructure measurement and inspection apparatus according to another embodiment;

FIG. 11 illustrates a configuration of a measurement object including a test element group (TEG); and

FIG. 12 illustrates a schematic configuration of an optical apparatus for three-dimensional nanostructure measurement and inspection and a three-dimensional nanostructure measurement and inspection apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an optical apparatus for three-dimensional nanostructure measurement and inspection, a three-dimensional nanostructure measurement and inspection apparatus including the same, and a three-dimensional nanostructure measurement and inspection method will be described in detail with reference to the accompanying drawings. Like reference numerals in the drawings will denote like elements, and sizes of elements in the drawings may be exaggerated for clarity and convenience of description. Also, the embodiments described below are merely examples, and various modifications may be made therein.

As used herein, the term “over” or “on” may include not only “directly over” or “directly on” but also “indirectly over” or “indirectly on”. As used herein, the singular forms “a”, “an”, and “the” are intended to include the plural forms as well, unless the context clearly indicates otherwise. Also, when something is referred to as “including” a component, another component may be further included unless specified otherwise.

The use of the terms “a”, “an”, and “the” and other similar indicative terms may be construed to cover both the singular and the plural. Unless there is an explicit order or a contrary description, operations constituting a method may be performed in a suitable order and are not necessarily limited to the described order.

Also, as used herein, the terms “units” and “modules” may refer to units that perform at least one function or operation, and the units may be implemented as hardware or software or a combination of hardware and software.

Connections or connection members of lines between the elements illustrated in the drawings may illustratively represent functional connections and/or physical or logical connections and may be represented as various replaceable or additional functional connections, physical connections, or logical connections in an actual apparatus.

All examples or illustrative terms used herein are merely intended to describe the technical concept of the disclosure in detail, and the scope of the disclosure is not limited by these examples or illustrative terms unless otherwise defined in the appended claims.

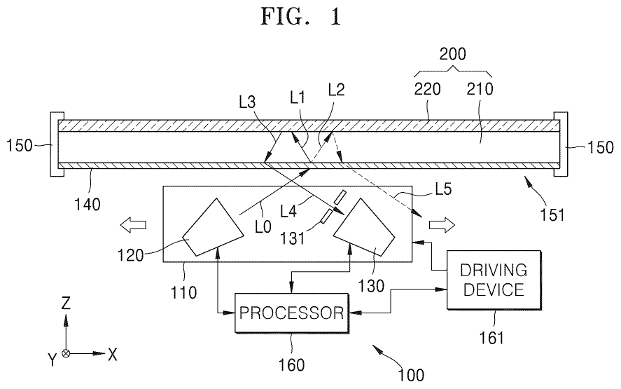

FIG. 1 illustrates a schematic configuration of an optical apparatus for three-dimensional nanostructure measurement and inspection and a three-dimensional nanostructure measurement and inspection apparatus according to an embodiment. Referring to FIG. 1, a three-dimensional nanostructure measurement and inspection apparatus 100 according to an embodiment may include an illumination system 120 configured to provide illumination light to a measurement object 200, a photodetector 130 configured to detect light from the measurement object 200, a meta deflector 140 to be provided on a substrate 210 of the measurement object 200 to negatively deflect the illumination light, and a processor 160 configured to control operations of the illumination system 120 and the photodetector 130 and analyze a three-dimensional nanostructure 220 of the measurement object 200 based on an output of the photodetector 130. Here, the illumination system 120, the photodetector 130, and the meta deflector 140 may form an optical module 110 for three-dimensional nanostructure measurement and inspection.

The measurement object 200 may include a substrate 210 including a first surface and a second surface opposing each other, and a three-dimensional nanostructure 220 provided on the first surface of the substrate 210. In some embodiments, when the substrate 210 is a silicon wafer, the first surface may correspond to a front surface of the silicon wafer where microelectronic devices or integrated circuits (ICs) are fabricated, and the second surface may correspond to a rear surface of the silicon wafer, which may primarily server as mechanical support and may be unprocessed or subjected to minimal processing. The three-dimensional nanostructure 220 may include various optical components or electronic components including structures of micrometer or less, that is, a nanometer scale. For example, the three-dimensional nanostructure 220 may include various types of couplers used in augmented reality (AR) devices, virtual reality (VR) devices, extended reality (XR) devices, and the like, or intermediate structures for the respective process operations of manufacturing the same. Also, the three-dimensional nanostructure 220 may include various 3D memories such as 3D DRAMs, high-bandwidth memories (HBMs), and vertical NAND (VNAND) flash memories, various integrated circuits, or intermediate structures for the respective process operations of manufacturing the same.

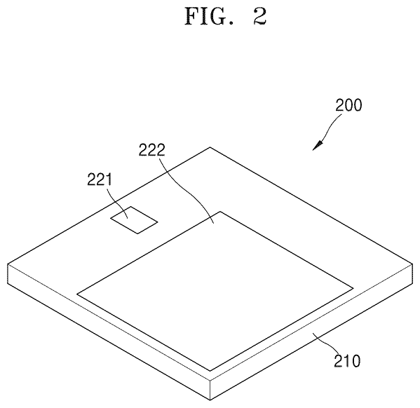

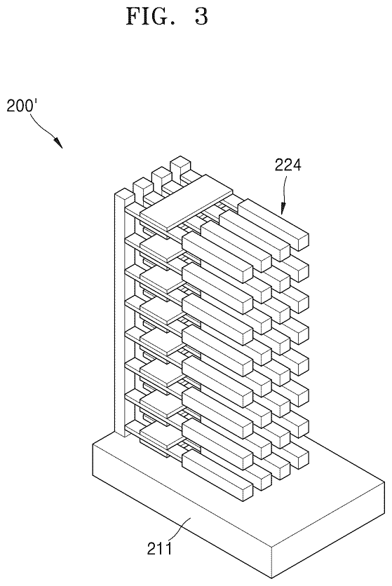

FIGS. 2 and 3 illustrate examples of a three-dimensional nanostructure of the measurement object 200. Referring to FIG. 2, the measurement object 200 may include a substrate 210, and an input coupler 221 and an output coupler 222 provided on the substrate 210. The substrate 210 may include a light guide plate having relatively high transmittance for visible light. The input coupler 221 may couple light input from the outside to the inside of the substrate 210. The output coupler 222 may output light from the inside of the substrate 210 toward the outside of the substrate 210, for example, toward the user's eyes. The input coupler 221 and the output coupler 222 may be a three-dimensional nanostructure having nano-scale lattice structures arranged in a period of tens of nm to hundreds of nm.

Referring to FIG. 3, a measurement object 200′ may include a substrate 211 and an integrated circuit 224 provided on the substrate 211. In this case, the substrate 211 may be a semiconductor wafer. The integrated circuit 224 may be a three-dimensional nanostructure including nano-scale electronic components such as various lines, field effect transistors, and capacitors having a size of several nm to hundreds of nm. The surface of the substrate 211 on which the integrated circuit 224 is mounted may be referred to as the front surface of the substrate 211, while the opposite surface may be referred to as the rear surface of the substrate 211. In some embodiments, the optical module 110 may be positioned to face the rear surface of the substrate 211, to allow light emitted from the illumination system 120 to enter the measurement object 200′ through the rear surface of the substrate 211.

Referring back to FIG. 1, the three-dimensional nanostructure measurement and inspection apparatus 100 according to an embodiment may further include a holder 150 configured to secure the measurement object 200 in place. The holder 150 may be provided to fix, grip, or support an edge portion of the measurement object 200 to maintain its position during inspection. Also, the holder 150 may include an opening 151 provided to allow the illumination light to be incident on the measurement object 200. For example, the opening 151 may be positioned such that the lower surface of the measurement object 200, that is, the second surface of the substrate 210 opposite to the first surface of the substrate 210 of the measurement object 200 with the three-dimensional nanostructure 220, is exposed to the illumination light. In this positional arrangement, the illumination light may enter the substrate 210 through the second surface and propagate into the interior of the substrate 210.

The meta deflector 140 may be provided on the substrate 210 of the measurement object 200 to face the three-dimensional nanostructure 220. In other words, the meta deflector 140 may be provided on the second surface of the substrate 210 that is the opposite side with respect to the three-dimensional nanostructure 220. In an example, the meta deflector 140 may be directly formed on the second surface of the substrate 210 or may be separately provided and then attached to the second surface of the substrate 210. The meta deflector 140 may extend along a plane (i.e., X-Y plane) including a first direction (i.e., X-axis direction) and a second direction (i.e., Y-axis direction) perpendicularly intersecting the first direction. The three-dimensional nanostructure 220 and the meta deflector 140 may face each other with the substrate 210 therebetween in a third direction (i.e., Z-axis direction) perpendicularly intersecting the first direction and the second direction.

The meta deflector 140 may have a negative deflection characteristic that diffracts and deflects most of incident light in a negative (−) direction and does not diffract and deflect incident light in a positive (+) direction or diffracts and deflects incident light relatively little in the positive (+) direction. For this purpose, the meta deflector 140 may have a periodic transmission phase distribution of a sub-wavelength or less. For example, the meta deflector 140 may have a transmission phase distribution with a period of ⅔ or less of the wavelength of the illumination light.

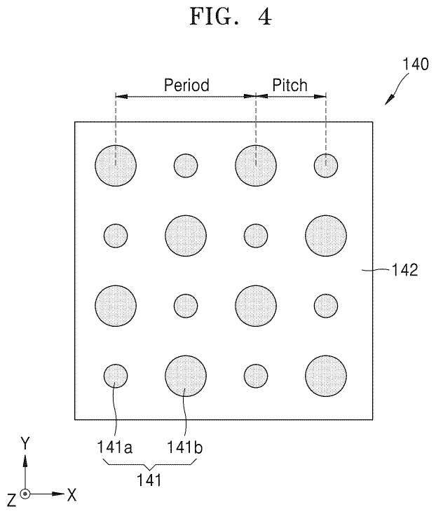

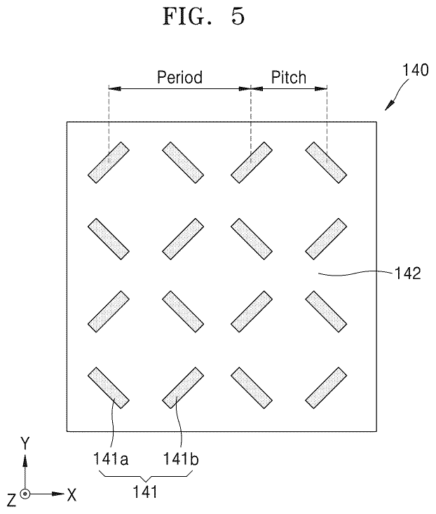

FIGS. 4 and 5 illustrate a configuration of a meta deflector according to an embodiment. Referring to FIG. 4, the meta deflector 140 may include a plurality of meta elements 141 that are periodically arranged in two dimensions. The plurality of meta elements 141 may be periodically arranged in two dimensions in the first direction and the second direction. The arrangement period and height of the plurality of meta elements 141 may vary depending on the type of the measurement object 200. For example, when the measurement object 200 is a 3D memory or integrated circuits, the wavelength of the illumination light may be about 1.2 μm to about 1.8 μm, the arrangement period of the plurality of meta elements 141 may be about 0.3 μm to about 1.2 μm that is ⅔ or less of the wavelength of the illumination light, and the height thereof may be about 70 nm to about 700 nm. In another example, when the measurement object 200 is an optical component used in an AR device, a VR device, an XR device, or the like, the wavelength of the illumination light may be about 400 nm to about 800 nm, the arrangement period of the plurality of meta elements 141 may be about 100 nm to about 550 nm that is ⅔ or less of the wavelength of the illumination light, and the height thereof may be about 70 nm to about 500 nm.

The meta deflector 140 may further include a filling material 142 filling the space around the plurality of meta elements 141. The plurality of meta elements 141 and the filling material 142 may include dielectric materials having different refractive indexes or may include metal and a dielectric material. For example, the plurality of meta elements 141 may include a high refractive index material such as amorphous silicon (a-Si), polycrystalline silicon (p-Si), hafnium oxide (HfO₂), or titanium oxide (TiO₂) having a relatively high refractive index, and the filling material 142 may include a low refractive index material such as silicon oxide (SiO₂) or spin-on-glass (SOG) having a relatively low refractive index. In another example, the plurality of meta elements 141 may include a low refractive index material, and the filling material 142 may include a high refractive index material. In another example, the plurality of meta elements 141 may include metal such as copper (Cu) or aluminum (Al) or a metal nitride such as TiN, and the filling material 142 may include a dielectric material or a metalloid such as amorphous silicon (a-Si), polycrystalline silicon (p-Si), or silicon oxide (SiO₂). In another example, the plurality of meta elements 141 may include a dielectric material, and the filling material 142 may include metal or a metal nitride.

The plurality of meta elements 141 may include a plurality of first meta elements 141a and a plurality of second meta elements 141b that are different from each other in terms of at least one of shape, size, and direction. The plurality of first meta elements 141a and the plurality of second meta elements 141b may be alternately arranged in the first direction and/or the second direction. The plurality of first meta elements 141a and the plurality of second meta elements 141b may be arranged at a pitch smaller than the arrangement period of the plurality of meta elements 141. Here, the pitch may be the distance between the centers of the first meta element and the second meta element adjacent to each other among the plurality of first meta elements 141a and the plurality of second meta elements 141b. For convenience, FIG. 4 illustrates that the plurality of meta elements 141 includes only two types of meta elements; however, the plurality of meta elements 141 may include three or more types of meta elements that are different from each other in terms of shape, size, or direction. The cross-sectional size or diameter of each of the plurality of first meta elements 141a and the plurality of second meta elements 141b may be smaller than the wavelength of the illumination light and particularly may be smaller than the arrangement period of the plurality of meta elements 141 and the pitch between the plurality of first meta elements 141a and the plurality of second meta elements 141b.

Although FIG. 4 illustrates that the plurality of first meta elements 141a and the plurality of second meta elements 141b have a circular shape and are different from each other in terms of only size, the disclosure is not limited thereto. Referring to FIG. 5, the plurality of first meta elements 141a and the plurality of second meta elements 141b may have a rectangular shape. The plurality of first meta elements 141a and the plurality of second meta elements 141b having a rectangular shape may be arranged in different directions. For example, each of the plurality of first meta elements 141a may extend in a first diagonal direction between the first direction and the second direction, and each of the plurality of second meta elements 141b may extend in a second diagonal direction perpendicularly intersecting the first diagonal direction.

In addition, the plurality of first meta elements 141a and the plurality of second meta elements 141b may have various other shapes such as a square shape, an elliptical shape, or a polygonal shape greater than or equal to a pentagonal shape in terms of the number of sides and may have a symmetrical shape or an asymmetrical shape in the first direction or the second direction. When the plurality of first meta elements 141a and the plurality of second meta elements 141b have a symmetrical shape, the size of the plurality of first meta elements 141a and the size of the plurality of second meta elements 141b may be different from each other. When the plurality of first meta elements 141a and the plurality of second meta elements 141b have an asymmetrical shape in the first direction or the second direction, the plurality of first meta elements 141a and the plurality of second meta elements 141b may be arranged to be rotated in different directions and/or may have different sizes. Also, although FIGS. 4 and 5 illustrate that the plurality of first meta elements 141a and the plurality of second meta elements 141b are arranged in a tetragonal grid pattern, the disclosure is not limited thereto. For example, the plurality of first meta elements 141a and the plurality of second meta elements 141b may be arranged in a hexagonal grid pattern.

Referring back to FIG. 1, the illumination system 120 may use light sources having different emission wavelengths depending on the characteristics of the measurement object 200. For example, when the measurement object 200 is a 3D memory or integrated circuits, the illumination system 120 may include a light source that emits illumination light having a wavelength of about 1.2 μm to about 1.8 μm. In another example, when the measurement object 200 is an optical component used in an AR device, a VR device, an XR device, or the like, the illumination system 120 may include a light source that emits illumination light having a wavelength of about 400 nm to about 800 nm. The illumination system 120 may emit illumination light of a single wavelength, may emit illumination light of a plurality of wavelengths, or may be configured to emit illumination light having wavelengths distributed in a particular wavelength range.

Illumination light L0 emitted from the illumination system 120 may be obliquely incident on the meta deflector 140. For this purpose, the illumination system 120 may be obliquely provided toward the meta deflector 140. First light L1 of a portion of the illumination light L0 incident on the meta deflector 140 may be negatively deflected to propagate into the substrate 210 of the measurement object 200, and second light L2 of another portion of the illumination light L0 may propagate into the substrate 210 of the measurement object 200 according to the general refraction law. For example, when the illumination light L0 is obliquely incident on the meta deflector 140 in a positive (+) first direction and a positive (+) third direction, the first light L1 may be diffracted and deflected in a negative (−) direction to propagate obliquely in the substrate 210 of the measurement object 200 in a negative (−) first direction and the positive (+) third direction. On the other hand, the second light L2 may propagate obliquely in the substrate 210 of the measurement object 200 in the positive (+) first direction and the positive (+) third direction.

The first light L1 may be incident on the three-dimensional nanostructure 220 of the measurement object 200 by passing through the substrate 210. The first light L1 may be negatively deflected by the meta deflector 140 and thus the wavenumber of the first light L1 may increase in the horizontal direction, that is, in the first direction. In other words, the first-direction wavenumber component of the first light L1 may be increased by the meta deflector 140. The first light L1 incident on the three-dimensional nanostructure 220 of the measurement object 200 with the wavenumber increased in the first direction may be coupled to a leaky guided mode of the three-dimensional nanostructure 220. Then, the first light L1 may propagate a certain distance in the negative (−) first direction in the three-dimensional nanostructure 220 and then may be output or leaked from the three-dimensional nanostructure 220 and thus may come out back to the substrate 210 as third light L3.

The third light L3 coming out from the three-dimensional nanostructure 220 to the substrate 210 after propagating a certain distance in the three-dimensional nanostructure 220 may propagate obliquely in the substrate 210 in the negative (−) first direction and the negative (−) third direction. Then, the third light L3 may be obliquely incident back on the meta deflector 140. The third light L3 obliquely incident on the meta deflector 140 may again be negatively deflected by the meta deflector 140 and thus may come out from the meta deflector 140 as fourth light L4.

The fourth light L4 diffracted and deflected by being negatively deflected by the meta deflector 140 may decrease in wavenumber in the horizontal direction, that is, in the first direction. The fourth light L4 may be detected by the photodetector 130 while propagating obliquely in the positive (+) first direction and the negative (−) third direction. The fourth light L4 detected by the photodetector 130 may include an interference pattern in the wavelength domain and space domain formed while propagating in the three-dimensional nanostructure 220, and thus, the fourth light L4 may be used as a signal for measurement and inspection of the three-dimensional nanostructure 220.

The second light L2 may propagate obliquely in the substrate 210 and thus may be incident on the three-dimensional nanostructure 220 and thereafter may propagate in the three-dimensional nanostructure 220 and then may be reflected to be incident back on the meta deflector 140. Thereafter, the resulting light may be deflected by the meta deflector 140 to come out from the meta deflector 140 as fifth light L5.

The propagation direction of the fourth light L4 and the propagation direction of the fifth light L5 may be approximately similar to each other. However, the position at which the fourth light L4 is emitted from the meta deflector 140 and the position at which the fifth light L5 is emitted from the meta deflector 140 may be different from each other. The photodetector 130 may be provided at a suitable distance from the illumination system 120 so as to detect only the fourth light L4 without detecting the fifth light L5. The distance between the illumination system 120 and the photodetector 130 may vary, for example, depending on the third-direction thickness of the substrate 210 of the measurement object 200 or depending on the third-direction distance between the meta deflector 140 and the three-dimensional nanostructure 220. Also, the photodetector 130 may include an aperture 131 for passing only the light coming in the same direction as the fourth light L4 and blocking the light coming in a different direction therefrom.

The photodetector 130 may include an image sensor. Also, the photodetector 130 may further include a spectroscope. In another example, the photodetector 130 may include a hyperspectral image sensor. The photodetector 130 may also be configured to further detect at least one of a propagation angle and a polarization component as well as a wavelength component of incident light.

The processor 160 may analyze the three-dimensional nanostructure 220 of the measurement object 200 based on the signal provided from the photodetector 130, for example, by using spectroscopic ellipsometry or the like. The processor 160 may be implemented as a dedicated integrated circuit chip or may be implemented as a programmable logic controller (PLC) configured to execute analysis software.

The illumination system 120 and the photodetector 130 may be provided on the same side with respect to the substrate 210. In other words, the illumination system 120 and the photodetector 130 may face the second surface of the substrate 210. Under the control by the processor 160, the illumination system 120 and the photodetector 130 may scan the three-dimensional nanostructure 220 of the measurement object 200 while moving in the first direction and the second direction. The illumination system 120 may be configured to emit illumination light L0 of a linear light beam extending in the second direction. In this case, the illumination system 120 and the photodetector 130 may scan the three-dimensional nanostructure 220 of the measurement object 200 while moving in the first direction. The optical apparatus for three-dimensional nanostructure measurement and inspection and/or the three-dimensional nanostructure measurement and inspection apparatus 100 may further include an optical module 110 in which the illumination system 120 and the photodetector 130 are mounted together. Then, the illumination system 120 and the photodetector 130 may be mounted in one optical module 110 and moved together.

The optical apparatus for three-dimensional nanostructure measurement and inspection and/or the three-dimensional nanostructure measurement and inspection apparatus 100 may further include a driving device 161 configured to move the illumination system 120 and the photodetector 130 under the control by the processor 160. The driving device 161 may be configured to move the optical module 110 under the control by the processor 160, enabling precise positioning during measurement or inspection. For example, the driving device 161 may include an actuator (e.g., piezoelectric actuators or voice coil actuators) to provide fine motion control, a linear motor or a stepper motor for larger-scale displacement, and/or the like. In some embodiments, the driving device 161 may further include position sensors to provide real-time feedback for closed-loop control, ensuring high accuracy and repeatability in the movement of the optical module 110.

The incident angle of the illumination light L0 incident on the meta deflector 140 may be preset such that the first light L1 is coupled to the leaky guided mode of the three-dimensional nanostructure 220. For example, the incident angle of the illumination light L0 with respect to the meta deflector 140 may be set such that the wavenumber of the light guided in the first direction in the leaky guided mode of the three-dimensional nanostructure 220 and the first-direction wavenumber of the first light L1 increased by the meta deflector 140 are similar to each other. In other words, depending on the waveguide effective index in the leaky guided mode of the three-dimensional nanostructure 220 and the degree to which the wavenumber is increased in the first direction by the meta deflector 140, the incident angle of the illumination light L0 may be set such that the first light L1 is coupled to the leaky guided mode of the three-dimensional nanostructure 220. In consideration of these points, the incident angle of the illumination light L0 on the meta deflector 140 may be set as in Equation 1 below.

$$\frac{Λ}{λ} = \frac{1}{sin θ + {n}_{n a n o , WG}} \qquad [ Equation 1 ]$$

In Equation 1, ∧ is the arrangement period of the plurality of meta elements 141 of the meta deflector 140, λ is the wavelength of the illumination light L0, θ is the incident angle of the illumination light L0, and n_{nano,WG} is the waveguide effective index in the leaky guided mode of the three-dimensional nanostructure 220. The waveguide effective index n_{nano,WG} in the leaky guided mode of the three-dimensional nanostructure 220 may be a unique value that varies depending on the overall structural characteristics of the three-dimensional nanostructure 220 to be measured, and may have the same value in the entire area of the three-dimensional nanostructure 220. The waveguide effective index may also vary depending on the wavelength, polarization, incident angle, and propagation direction of light incident on the three-dimensional nanostructure 220. The incident angle θ of the illumination light L0 may be the angle between the surface normal of the meta deflector 140 and the illumination light L0.

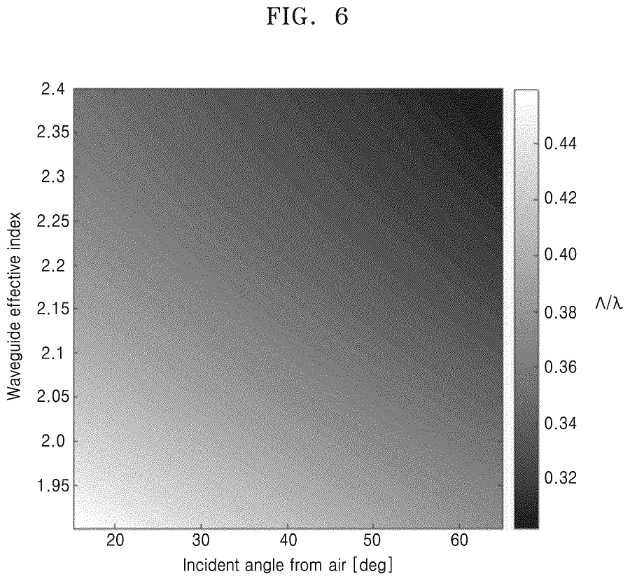

FIG. 6 is a graph illustrating the relationship between the waveguide effective index n_{nano,WG} in the leaky guided mode of the three-dimensional nanostructure 220 to be measured, the arrangement period ∧ of the plurality of meta elements 141 of the meta deflector 140, and the incident angle of the illumination light L0. In the graph of FIG. 6, the vertical axis on the left represents the waveguide effective index n_{nano,WG} in the leaky guided mode of the three-dimensional nanostructure 220, and the label on the right represents a value ∧/λ obtained by dividing the arrangement period ∧ of the plurality of meta elements 141 of the meta deflector 140 by the wavelength λ of the illumination light L0. As illustrated in FIG. 6, when the wavelength λ of the illumination light L0 is fixed, as the arrangement period ∧ of the plurality of meta elements 141 of the meta deflector 140 increases or as the waveguide effective index n_{nano,WG} in the leaky guided mode of the three-dimensional nanostructure 220 increases, the incident angle θ of the illumination light L0 on the meta deflector 140 for coupling the first light L1 to the leaky guided mode of the three-dimensional nanostructure 220 may decrease. Also, as the wavelength A of the illumination light L0 increases, the incident angle θ of the illumination light L0 on the meta deflector 140 for coupling the first light L1 to the leaky guided mode of the three-dimensional nanostructure 220 may increase.

The graph of FIG. 6 illustrates a case where the illumination light L0 propagates along a plane including the first direction and the third direction (i.e., X-Z plane); however, the propagation direction of the illumination light L0 is not limited thereto and the illumination light L0 may also propagate along a plane including the second direction and the third direction (i.e., Y-Z plane). Also, the illumination light L0 may propagate along a plane between the X-Z plane and the Y-Z plane. For example, the propagation direction of the illumination light L0 may be adjusted to the azimuth direction such that the structural characteristics of the three-dimensional nanostructure 220 may be measured in various directions. For this purpose, the driving device 161 may be configured to rotate the optical module 110 on a plane including the first direction and the second direction (i.e., X-Y plane) under the control by the processor 160.

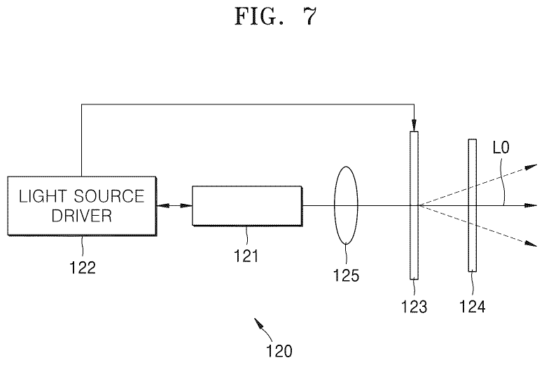

FIG. 7 illustrates a configuration of the illumination system 120. Referring to FIG. 7, the illumination system 120 may include a light source 121 and a light source driver 122. For convenience, only one light source 121 is illustrated in FIG. 7; however, the light source 121 may include an array of a plurality of laser light sources one-dimensionally or two-dimensionally arranged. Under the control by the processor 160, the light source driver 122 may control the light source 121 to adjust the on/off state of the light source 121, the pulse shape of the illumination light L0, the wavelength or intensity of the illumination light L0, and the like.

Also, the illumination system 120 may further include a collimating lens 125 for converting the illumination light L0 into parallel light. Also, the illumination system 120 may further include a beam deflector 123 for adjusting the propagation direction of the illumination light L0 and a polarization filter 124 for adjusting the polarization component of the illumination light L0.

FIG. 1 illustrates that the illumination system 120 is obliquely provided toward the meta deflector 140; however, the illumination system 120 may be provided in parallel to the X-Y plane and the illumination light L0 may be controlled to be obliquely incident on the meta deflector 140 by using the beam deflector 123. The beam deflector 123 may be, for example, a liquid crystal beam deflector, an optical phased array (OPA), or a mechanical beam deflector such as a galvano mirror.

Also, for convenience, only one polarization filter 124 is illustrated in FIG. 7; however, a plurality of polarization filters may be provided for a plurality of laser light sources. In another example, a plurality of polarizers may be provided in the form of an array in a single polarization filter 124 having a disk shape. In this case, under the control by the processor 160, the polarization filter 124 may be rotated in the optical path of the illumination light L0 or moved in a direction perpendicular to the optical axis to control the polarization of the illumination light L0.

The processor 160 may control the light source driver 122 of the illumination system 120 or the driving device 161 to adjust the wavelength, polarization, and azimuth direction of the illumination light L0 and the incident angle θ of the illumination light L0 incident on the meta deflector 140. The processor 160 may calculate a suitable incident angle θ of the illumination light L0 satisfying Equation 1, based on the wavelength, polarization, azimuth direction, and/or the like of the illumination light L0. For this purpose, the processor 160 may include data about the arrangement period ∧ of the plurality of meta elements 141 of the meta deflector 140 and data about the waveguide effective index n_{nano,WG} in the leaky guided mode of the three-dimensional nanostructure 220 according to the wavelength, polarization, incident angle, and azimuth direction of the illumination light. For example, the processor 160 may include a data input/output device and a memory for inputting and recording the above data. The processor 160 may calculate the incident angle θ of the illumination light L0 satisfying Equation 1, based on data about the arrangement period ∧ of the plurality of meta elements 141 of the meta deflector 140 and data about the waveguide effective index n_{nano,WG} in the leaky guided mode of the three-dimensional nanostructure 220 according to the wavelength, polarization, incident angle, and azimuth direction of the illumination light, and may adjust the incident angle θ of the illumination light L0 incident on the meta deflector 140 by directly controlling the beam deflector 123 or controlling the beam deflector 123 through the light source driver 122 based on the calculation result. The processor 160 may measure various different structural characteristics of the three-dimensional nanostructure 220 at the same position by controlling at least one of the wavelength, polarization, and azimuth direction of the illumination light L0.

According to an embodiment, because the illumination light L0 is radiated onto the rear surface (i.e., the second surface) of the substrate 210 opposite to the front surface (i.e., the first surface) on which the three-dimensional nanostructure 220 is formed, even when the total height of the three-dimensional nanostructure 220 of the measurement object 200 is high, the illumination light L0 may be maximally concentrated on a structural area in which a fine change of the three-dimensional nanostructure 220 occurs. Also, because the illumination light L0 negatively deflected by the meta deflector 140 provided on the rear surface of the substrate 210 with the three-dimensional nanostructure 220 formed thereon and then incident on the three-dimensional nanostructure 220 has an increased wavenumber in the horizontal direction on the X-Y plane, the three-dimensional nanostructure 220 may be measured and inspected with a further improved resolution or a further improved signal-to-noise ratio (SNR).

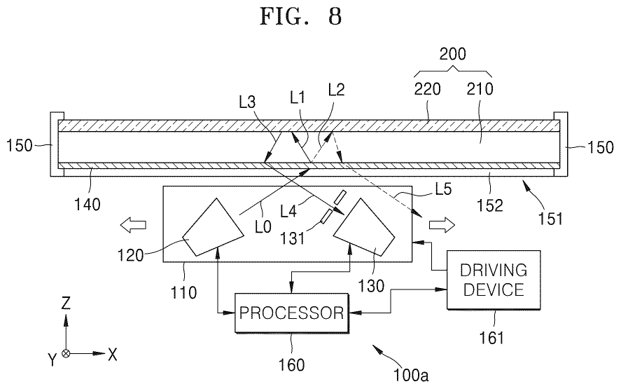

FIG. 8 illustrates a schematic configuration of an optical apparatus for three-dimensional nanostructure measurement and inspection and a three-dimensional nanostructure measurement and inspection apparatus according to another embodiment. Referring to FIG. 8, an optical apparatus for three-dimensional nanostructure measurement and inspection and/or a three-dimensional nanostructure measurement and inspection apparatus 100a according to another embodiment may further include a transparent support 152 provided in the opening 151 of the holder 150. The transparent support 152 may include, for example, glass or a transparent polymer; however, the disclosure is not necessarily limited thereto. The substrate 210 of the measurement object 200 may be supported by the transparent support 152 on the opening 151 of the holder 150. In this case, the meta deflector 140 may contact the transparent support 152. In order to prevent or reduce unwanted optical effects such as reflection and scattering of the illumination light L0, an anti-reflection coating may be provided on the lower surface and upper surface of the transparent support 152. The anti-reflection coating may be implemented as a dielectric film configured to match the refractive index of the transparent support 152.

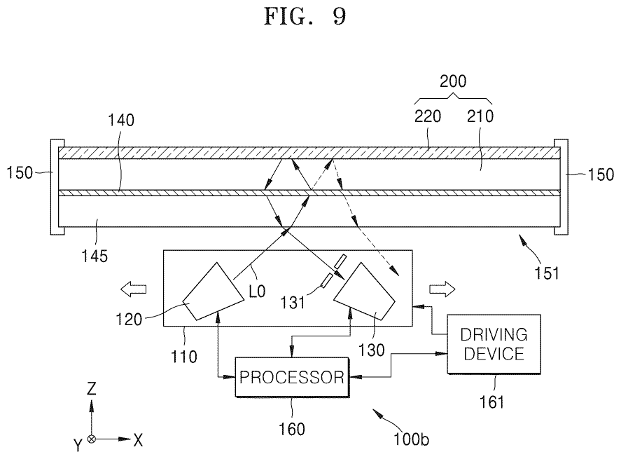

FIG. 9 illustrates a schematic configuration of an optical apparatus for three-dimensional nanostructure measurement and inspection and a three-dimensional nanostructure measurement and inspection apparatus according to another embodiment. Referring to FIG. 9, an optical apparatus for three-dimensional nanostructure measurement and inspection and/or a three-dimensional nanostructure measurement and inspection apparatus 100b according to another embodiment may further include a carrier substrate 145 with the meta deflector 140. According to an embodiment, the meta deflector 140 may not be directly provided on the second surface of the substrate 210 of the measurement object 200 but may be provided separately from the substrate 210 of the measurement object 200. The carrier substrate 145 may include glass or a transparent polymer. The carrier substrate 145 may include a first surface and a second surface opposing each other, and the meta deflector 140 may be provided on the first surface of the carrier substrate 145. The carrier substrate 145 may be provided such that the first surface of the carrier substrate 145 provided with the meta deflector 140 faces the second surface of the substrate 210 of the measurement object 200 and the second surface of the carrier substrate 145 faces the opening 151 of the holder 150. Then, the illumination light L0 may be obliquely incident on the second surface of the carrier substrate 145 and then may be negatively deflected by the meta deflector 140 on the first surface of the carrier substrate 145 and provided to the three-dimensional nanostructure 220 of the measurement object 200.

In an embodiment, the carrier substrate 145 may be temporarily bonded to the substrate 210 of the measurement object 200. For example, in the state where the carrier substrate 145 is temporarily bonded to the substrate 210 of the measurement object 200 such that the meta deflector 140 contacts the substrate 210 of the measurement object 200, a three-dimensional nanostructure 220 may be manufactured on the first surface of the substrate 210 and a measurement and inspection may also be performed on the three-dimensional nanostructure 220. After the manufacturing process and the measurement and inspection on the three-dimensional nanostructure 220 are completed, the measurement object 200 may be carried by using the carrier substrate 145. Also, by using the carrier substrate 145, the measurement object 200 may be transferred to a substrate with another electronic device or element formed thereon. Thereafter, the carrier substrate 145 may be debonded from the measurement object 200 by using laser irradiation, heat treatment, or the like. In another example, after the manufacturing process and the measurement and inspection on the three-dimensional nanostructure 220 are completed, the carrier substrate 145 may be debonded from the measurement object 200. The meta deflector 140 may function as a debonding layer for debonding the carrier substrate 145 from the measurement object 200. The carrier substrate 145 debonded therefrom and the meta deflector 140 may be reused after being cleaned.

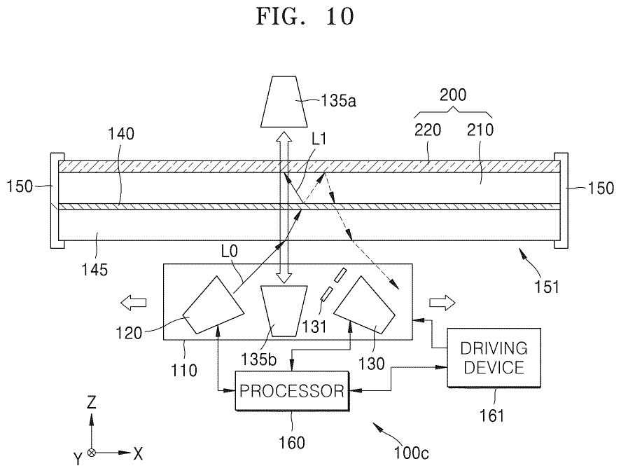

FIG. 10 illustrates a schematic configuration of an optical apparatus for three-dimensional nanostructure measurement and inspection and a three-dimensional nanostructure measurement and inspection apparatus according to another embodiment. Referring to FIG. 10, an optical apparatus for three-dimensional nanostructure measurement and inspection and/or a three-dimensional nanostructure measurement and inspection apparatus 100c according to another embodiment may further include a first photodetector 135a and a second photodetector 135b configured to detect light to investigate a defect in the three-dimensional nanostructure 220 based on the detected light. When there is a defect in the three-dimensional nanostructure 220, a portion of the light coupled to the leaky guided mode of the three-dimensional nanostructure 220 may be scattered in a direction perpendicular to the surface of the three-dimensional nanostructure 220, that is, in the third direction. Thus, in order to measure the light scattered in the third direction from the three-dimensional nanostructure 220, the first and second photodetectors 135a and 135b may be provided to perpendicularly face the surface of the three-dimensional nanostructure 220. The first and second photodetectors 135a and 135b may be, for example, an array of avalanche photodiodes having relatively high sensitivity or an image sensor having relatively high sensitivity.

The light scattered by the defect of the three-dimensional nanostructure 220 may propagate upward, that is, in the positive (+) third direction (i.e., +Z-axis direction), and/or downward, that is, in the negative (−) third direction (i.e., −Z-axis direction), with respect to the surface of the three-dimensional nanostructure 220. Thus, the first photodetector 135a may be provided to face the upper surface of the three-dimensional nanostructure 220, and the second photodetector 135b may be provided to face the lower surface of the three-dimensional nanostructure 220. The second photodetector 135b may be provided to face, for example, the second surface of the substrate 210 of the measurement object 200 or the second surface of the carrier substrate 145. FIG. 10 illustrates that the first and second photodetectors 135a and 135b are respectively provided over and under the three-dimensional nanostructure 220; however, the disclosure is not necessarily limited thereto and any one of the first and second photodetectors 135a and 135b may be omitted.

Also, the first and second photodetectors 135a and 135b may be provided to face, in the third direction, an area in which the illumination light (i.e., the first light L1) negatively deflected by the meta deflector 140 is incident on the three-dimensional nanostructure 220 on a plane including the first direction and the second direction (i.e., X-Y plane). When the illumination system 120 moves in the first direction and/or the second direction, the first and second photodetectors 135a and 135b may also be configured to move in the first direction and/or the second direction in accordance with the movement of the illumination system 120. For example, the second photodetector 135b may be mounted in the optical module 110 together with the illumination system 120 and the photodetector 130. The first photodetector 135a may move independently through a separate driving device. In another example, the optical module 110 may extend over the three-dimensional nanostructure 220 of the measurement object 200 such that the first photodetector 135a may be further mounted.

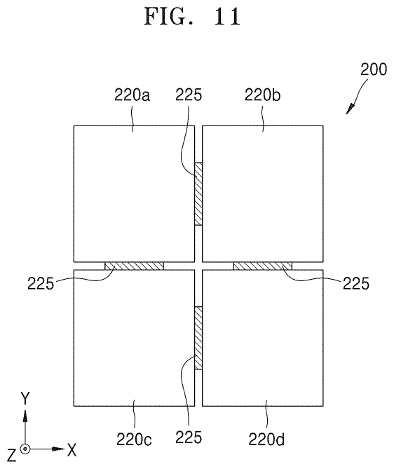

FIG. 11 illustrates a configuration of a measurement object 200 including a test element group (TEG) area. Referring to FIG. 11, the measurement object 200 may include a plurality of chips 220a, 220b, 220c, and 220d one-dimensionally and/or two-dimensionally arranged. A three-dimensional nanostructure 220 may be provided on a first surface of each of the plurality of chips 220a, 220b, 220c, and 220d. Each of the plurality of chips 220a, 220b, 220c, and 220d may be spaced apart from other adjacent chips in the first direction and/or the second direction.

Also, the measurement object 200 may include a TEG area 225 provided between two adjacent chips among the plurality of chips 220a, 220b, 220c, and 220d. The TEG area 225 may be in the form of a thin film having a flat surface without any pattern or may have a surface having a predetermined pattern. In order to measure the measurement object 200, measurement may be first performed on the TEG area 225 to beforehand measure the response characteristics of the illumination light L0 to the meta deflector 140 or the process profile characteristics of the three-dimensional nanostructure 220. Thereafter, based on the result of the measurement performed on the TEG area 225, the processor 160 may infer the data obtained during the measurement of the three-dimensional nanostructure 220, to improve the measurement accuracy. For example, the relationship between the result of the measurement performed on the TEG area 225 and the actual measurement result of the three-dimensional nanostructure 220 may be learned through a machine learning algorithm, and the measurement result of the three-dimensional nanostructure 220 may be accurately inferred based thereon.

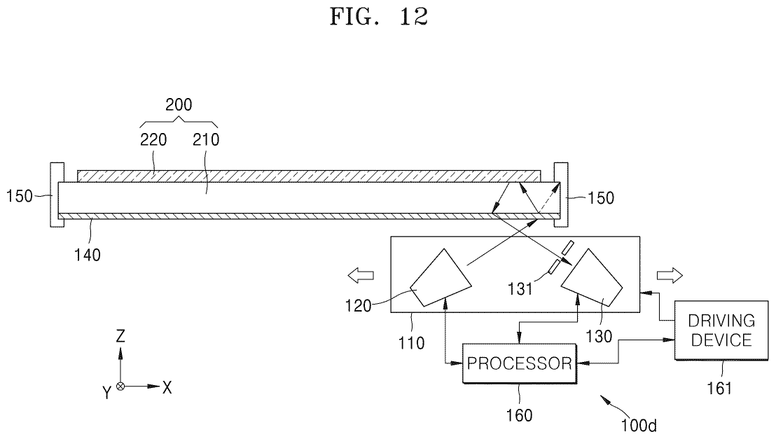

FIG. 12 illustrates a schematic configuration of an optical apparatus for three-dimensional nanostructure measurement and inspection and a three-dimensional nanostructure measurement and inspection apparatus 100d according to another embodiment. Referring to FIG. 12, when the illumination light negatively deflected by the meta deflector 140 propagates obliquely toward the three-dimensional nanostructure 220, the width of the meta deflector 140 in the first direction and/or the second direction may be greater than the width of the three-dimensional nanostructure 220 such that the illumination light may also be radiated onto the edge of the three-dimensional nanostructure 220. For example, the meta deflector 140 may protrude and extend further in the first direction and/or the second direction in comparison with the three-dimensional nanostructure 220.

The present disclosure provides one or more embodiments including but not limited to the following embodiments.

One or more embodiments relate to a method and an apparatus for inspecting 3D nanostructures, may provide an illumination system configured to introduce and extract light through the rear surface of a measurement target (e.g., a semiconductor substrate such as a wafer). The 3D nanostructures may support leaky guided modes, which allow light to couple in and out efficiently. The apparatus may include a meta deflector to deflect incoming light at a negative angle, increasing the light's horizontal wavenumber. This allows the light to couple into the leaky guided modes of the 3D nanostructures formed on the front surface of the substrate. As the light travels through the 3D nanostructures, the light leaks back out through the substrate and passes again through the meta deflector, which adjusts its wavenumber so the light may exit through the rear surface into the air. The emitted signal is then detected and used for measurement and inspection.

(1) According to an embodiment, an optical apparatus for three-dimensional nanostructure measurement and inspection may include a illumination system configured to provide illumination light to a measurement object including a substrate including a first surface with a three-dimensional nanostructure and a second surface opposing the first surface, a photodetector configured to detect light from the measurement object, and a meta deflector provided on the second surface of the substrate, wherein the illumination system may be provided such that the illumination light is obliquely incident on the meta deflector, and the meta deflector may be configured to negatively deflect the illumination light.

(2) The meta deflector may include a plurality of meta elements that are periodically arranged in two dimensions.

(3) The plurality of meta elements of the meta deflector may include a plurality of first meta elements and a plurality of second meta elements that are different from each other in terms of at least one of shape, size, and direction.

(4) The plurality of first meta elements and the plurality of second meta elements may be alternately arranged in a first direction and/or a second direction intersecting the first direction.

(5) An arrangement period of the plurality of meta elements of the meta deflector may be ⅔ or less of a wavelength of the illumination light.

(6) The illumination system may be configured such that a wavelength, polarization, and azimuth direction of the illumination light and an incident angle of the illumination light incident on the meta deflector are adjusted.

(7) An incident angle of the illumination light incident on the meta deflector may be set such that the illumination light negatively deflected by the meta deflector is coupled to a leaky guided mode of the three-dimensional nanostructure.

(8) The optical apparatus for three-dimensional nanostructure measurement and inspection may further include a carrier substrate with the meta deflector, wherein the carrier substrate may include a first surface and a second surface opposing each other.

(9) The meta deflector may be provided on the first surface of the carrier substrate, and the carrier substrate may be provided such that the first surface of the carrier substrate with the meta deflector faces the second surface of the substrate of the measurement object.

(10) The carrier substrate may be temporarily bonded to the substrate of the measurement object.

(11) The optical apparatus for three-dimensional nanostructure measurement and inspection may further include an additional photodetector configured to investigate a defect of the three-dimensional nanostructure, wherein the additional photodetector may be provided to perpendicularly face a surface of the three-dimensional nanostructure.

(12) The additional photodetector may be provided to face an area in which the illumination light negatively deflected by the meta deflector is incident on the three-dimensional nanostructure.

(13) The illumination system and the photodetector may be configured to scan the three-dimensional nanostructure while moving in a first direction and/or a second direction.

(14) The additional photodetector may be configured to move in the first direction and/or the second direction in accordance with the movement of the illumination system.

(15) The photodetector may include a spectroscope or a hyperspectral image sensor and may be configured to detect at least one of a wavelength component, propagation angle, and polarization component of incident light.

(16) According to an embodiment, a three-dimensional nanostructure measurement and inspection apparatus may include a illumination system configured to provide illumination light to a measurement object including a substrate including a first surface with a three-dimensional nanostructure and a second surface opposing the first surface, a photodetector configured to detect light from the measurement object, a meta deflector provided on the second surface of the substrate, and a processor configured to control operations of the illumination system and the photodetector and analyze the three-dimensional nanostructure based on an output of the photodetector, wherein the illumination system is provided such that the illumination light is obliquely incident on the meta deflector, and the meta deflector is configured to negatively deflect the illumination light.

(17) The processor may be configured to calculate an incident angle of the illumination light incident on the meta deflector such that the illumination light negatively deflected by the meta deflector is coupled to a leaky guided mode of the three-dimensional nanostructure.

(18) The meta deflector may include a plurality of meta elements that are periodically arranged in two dimensions.

(19) The processor may be configured to adjust at least one of a wavelength, polarization, and azimuth direction of the illumination light, and the processor may be configured to calculate the incident angle of the illumination light based on data about an arrangement period of the plurality of meta elements of the meta deflector and data about a waveguide effective index in the leaky guided mode of the three-dimensional nanostructure according to the wavelength, polarization, incident angle, and azimuth direction of the illumination light, and adjust the incident angle of the illumination light based on a result of the calculating.

(20) The measurement object may include a plurality of chips and a TEG area provided between two chips among the plurality of chips, and the processor may be configured to infer data obtained during measurement of the three-dimensional nanostructure, based on a result of measurement performed on the TEG area.

(21) According to an embodiment, a three-dimensional nanostructure measurement and inspection method on a measurement object including a substrate including a first surface with a three-dimensional nanostructure and a second surface opposing the first surface may include arranging a meta deflector on the second surface of the substrate, providing illumination light to be obliquely incident on the meta deflector, negatively deflecting the illumination light by the meta deflector, coupling the negatively deflected illumination light to a leaky guided mode of the three-dimensional nanostructure, detecting light from the three-dimensional nanostructure by a photodetector, and analyzing the three-dimensional nanostructure based on an output of the photodetector.

(22) The providing of the illumination light to be obliquely incident on the meta deflector may include calculating an incident angle of the illumination light incident on the meta deflector such that the illumination light negatively deflected by the meta deflector is coupled to the leaky guided mode of the three-dimensional nanostructure, and adjusting the incident angle of the illumination light based on a result of the calculating.

(23) The measurement object may include a plurality of chips and a TEG area provided between two chips among the plurality of chips, and the three-dimensional nanostructure measurement and inspection method may further include inferring data obtained during measurement of the three-dimensional nanostructure, based on a result of measurement performed on the TEG area.

Although the optical apparatus for three-dimensional nanostructure measurement and inspection, the three-dimensional nanostructure measurement and inspection apparatus including the same, and the three-dimensional nanostructure measurement and inspection method have been described above with reference to the embodiments illustrated in the drawings, these are merely examples and those of ordinary skill in the art will understand that various modifications and other equivalent embodiments may be made therefrom. Therefore, the described embodiments should be considered in descriptive sense only and not for purposes of limitation. The scope of the disclosure should be defined not by the foregoing description but by the appended claims, and all differences within the scope equivalent thereto should be construed as being included in the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An optical apparatus comprising:
an illumination system configured to emit illumination light to a measurement object;
a photodetector configured to detect light from the measurement object; and
based on the measurement object comprising a three-dimensional nanostructure and a substrate, and the substrate comprising a first surface on which the three-dimensional nanostructure is mounted and a second surface that opposes the first surface, a meta deflector configured to be provided on the second surface of the substrate,
wherein the illumination system is configured to emit the illumination light to be obliquely incident on the meta deflector, and
the meta deflector is configured to negatively deflect the illumination light.

2. The optical apparatus of claim 1, wherein the meta deflector comprises a plurality of meta elements that are periodically arranged in two dimensions.

3. The optical apparatus of claim 2, wherein the plurality of meta elements of the meta deflector comprise a plurality of first meta elements and a plurality of second meta elements, which are different from each other in terms of at least one of a shape, a size, and a direction, and
the plurality of first meta elements and the plurality of second meta elements are alternately arranged in at least one of a first direction or a second direction intersecting the first direction.

4. The optical apparatus of claim 2, wherein an arrangement period of the plurality of meta elements of the meta deflector is less than or equal to ⅔ of a wavelength of the illumination light.

5. The optical apparatus of claim 1, wherein the illumination system is further configured such that a wavelength, polarization, and an azimuth direction of the illumination light and an incident angle of the illumination light incident on the meta deflector are adjusted.

6. The optical apparatus of claim 1, wherein an incident angle of the illumination light incident on the meta deflector is set such that the illumination light negatively deflected by the meta deflector is coupled to a leaky guided mode of the three-dimensional nanostructure.

7. The optical apparatus of claim 1, further comprising a carrier substrate with the meta deflector,
wherein the carrier substrate includes a first surface and a second surface opposing each other,
the meta deflector is provided on the first surface of the carrier substrate, and
the carrier substrate is provided such that the first surface of the carrier substrate with the meta deflector faces the second surface of the substrate of the measurement object.

8. The optical apparatus of claim 7, wherein the carrier substrate is bonded to the substrate of the measurement object during measurement and inspection, and is separated from the substrate of the measurement object before and after the measurement and inspection.

9. The optical apparatus of claim 1, further comprising an additional photodetector configured to investigate a defect of the three-dimensional nanostructure,
wherein the additional photodetector is provided to perpendicularly face a surface of the three-dimensional nanostructure.

10. The optical apparatus of claim 9, wherein the additional photodetector is provided to face an area in which the illumination light negatively deflected by the meta deflector is incident on the three-dimensional nanostructure.

11. The optical apparatus of claim 9, wherein the illumination system and the photodetector are configured to scan the three-dimensional nanostructure while moving in at least one of a first direction or a second direction, and
the additional photodetector is configured to move in at least the first direction or the second direction in accordance with a movement of the illumination system.

12. The optical apparatus of claim 1, wherein the photodetector comprises a spectroscope or a hyperspectral image sensor and is configured to detect at least one of a wavelength component, a propagation angle, and a polarization component of incident light.

13. A three-dimensional nanostructure measurement and inspection apparatus comprising:
an illumination system configured to emit illumination light to a measurement object;
a photodetector configured to detect light from the measurement object;
based on the measurement object comprising a three-dimensional nanostructure and a substrate, and the substrate comprising a first surface on which the three-dimensional nanostructure is mounted and a second surface that opposes the first surface, a meta deflector is configured to be provided on the second surface of the substrate; and
a processor configured to control operations of the illumination system and the photodetector and analyze the three-dimensional nanostructure based on an output of the photodetector,
wherein the illumination system is configured to emit the illumination light to be obliquely incident on the meta deflector, and
the meta deflector is configured to negatively deflect the illumination light.

14. The three-dimensional nanostructure measurement and inspection apparatus of claim 13, wherein the processor is further configured to calculate an incident angle of the illumination light incident on the meta deflector such that the illumination light negatively deflected by the meta deflector is coupled to a leaky guided mode of the three-dimensional nanostructure.

15. The three-dimensional nanostructure measurement and inspection apparatus of claim 14, wherein the meta deflector comprises a plurality of meta elements that are periodically arranged in two dimensions.

16. The three-dimensional nanostructure measurement and inspection apparatus of claim 15, wherein the processor is further configured to adjust at least one of a wavelength, polarization, and an azimuth direction of the illumination light, and
the processor is further configured to:
calculate the incident angle of the illumination light based on data about an arrangement period of the plurality of meta elements of the meta deflector and data about a waveguide effective index in the leaky guided mode of the three-dimensional nanostructure according to the wavelength, the polarization, the incident angle, and the azimuth direction of the illumination light, and
adjust the incident angle of the illumination light based on a result of the calculating.

17. The three-dimensional nanostructure measurement and inspection apparatus of claim 13, wherein the measurement object comprises a plurality of chips and a test element group (TEG) area provided between two chips among the plurality of chips, and
the processor is further configured to infer data obtained during measurement of the three-dimensional nanostructure, based on a result of measurement performed on the TEG area.

18. A method for a measurement object comprising a substrate, the substrate comprising a first surface on which a three-dimensional nanostructure is mounted and a second surface opposing the first surface, the method comprising:
arranging a meta deflector on the second surface of the substrate;
emitting illumination light to be obliquely incident on the meta deflector;
negatively deflecting the illumination light by the meta deflector;
coupling the negatively deflected illumination light to a leaky guided mode of the three-dimensional nanostructure;
detecting light from the three-dimensional nanostructure by a photodetector; and
analyzing the three-dimensional nanostructure based on an output of the photodetector.

19. The method of claim 18, wherein
the emitting of the illumination light to be obliquely incident on the meta deflector comprises:
calculating an incident angle of the illumination light incident on the meta deflector such that the illumination light negatively deflected by the meta deflector is coupled to the leaky guided mode of the three-dimensional nanostructure; and
adjusting the incident angle of the illumination light based on a result of the calculating.

20. The method of claim 18, wherein the measurement object comprises a plurality of chips and a test element group (TEG) area provided between two chips among the plurality of chips, and
the method further comprises inferring data obtained during measurement of the three-dimensional nanostructure, based on a result of measurement performed on the TEG area.
